(19) United States
(12) Patent Application Publication
(10) Pub. No.: US 2013/0141076 A1
(43) Pub. Date: Jun. 6, 2013

(54) Spread Spectrum Clock Signal Detection System and Method

(71) Applicant: Ziche Zhang, Chengdu (CN)

(72) Inventor: Ziche Zhang, Chengdu (CN)

(73) Assignee: IPGoal Microelectronics (Sichuan Co., Ltd.)

(21) Appl. No.: 13/610,854

(22) Filed: Sep. 11, 2012

(30) Foreign Application Priority Data
Dec. 2, 2011 (CN) 201110393855.1

(51) Int. Cl. G01R 23/02

(52) U.S. Cl. 324/76.19

(57) ABSTRACT

A spread spectrum clock signal detection system includes: a spread spectrum clock signal input terminal; a reference clock signal input terminal; a frequency difference detection module connected with the spread spectrum clock signal input terminal and the reference clock signal input terminal; a spread spectrum pulse detection module connected with the spread spectrum clock signal input terminal, the reference clock signal input terminal and the frequency difference detection module; a spread spectrum value calculating module connected with the spread spectrum pulse detection module; a spread spectrum value reference input terminal connected with the spread spectrum value calculating module; and an output module connected with the spread spectrum value calculating module, wherein the spread spectrum clock signal detection system judges whether the spread spectrum clock signal exists according to the information of the spread spectrum value with magnitude and direction. A spread spectrum clock signal detection method is also provided.

### BACKGROUND OF THE PRESENT INVENTION

1. Field of Invention

The present invention relates to a signal detection system and method, and more particularly to a spread spectrum clock signal detection system for detecting whether a spread spectrum clock signal exists in a high speed serial data transmission system and a spread spectrum clock signal detection method therefor.

2. Description of Related Arts

Electromagnetic interference (EMI) are classified into two species: conducted interference and radiation interference. The conducted interference means coupling or interfering a signal in an electrical network into another electrical network by a conducting medium. The radiation interference means coupling or interfering a signal in an electrical network into another electrical network by an interference source through the space. In the design of the high-speed circuit board and its system, the elements, such as the high frequency signal lines, the pins of the integrated circuit, various connectors, and etc., could become radiation interference sources with the characteristics of antenna, which could emit electromagnetic waves and affect the normal work of other systems or other subsystems in the same system. Therefore, reducing electromagnetic interference is an important factor that the electronic system designer should consider.

In the high speed serial data transmission system, a spread spectrum clock circuit is often used to effectively reduce EMI radiation. However, while reducing EMI radiation with the spread spectrum clock circuit, the fact that the high speed serial data transmission system works in varying frequency increases the difficulty for the receiving terminal to receive the data, so it is necessary for the receiving terminal to verify the data sent by the sending terminal. Accordingly, the spread spectrum clock circuit could accurately and rapidly verify whether the data sent by the sending terminal is correct or conforms to the data transmission protocol. Therefore, the error could be located conveniently and the system parameters could be reasonably adjusted according to the spread spectrum clock signal output by the spread spectrum clock circuit. In such a manner that the high speed serial data transmission system always works in the best state under various data transmission protocols, and the spread spectrum clock circuit adjusts the clock data recovery circuit to work in the best parameters. So it is necessary to provide a spread spectrum clock signal detection system for detecting whether a spread spectrum clock signal exists in a high speed serial data transmission system and a spread spectrum clock signal detection method therefor.

### SUMMARY OF THE PRESENT INVENTION

In view of the above description, it is necessary to provide a spread spectrum clock signal detection system for detecting whether a spread spectrum clock signal exists in a high speed serial data transmission system and a spread spectrum clock signal detection method therefor.

A spread spectrum clock signal detection system is used to detect whether a spread spectrum clock signal exists in a high speed serial data transmission system. The spread spectrum clock signal detection system comprises:

a spread spectrum clock signal input terminal for inputting the spread spectrum clock signal;

a reference clock signal input terminal for inputting a reference clock signal;

a frequency difference detection module, connected with the spread spectrum clock signal input terminal and the reference clock signal input terminal, for detecting whether a frequency difference exists between the spread spectrum clock signal and the reference clock signal;

a spread spectrum pulse detection module, connected with the spread spectrum clock signal input terminal, the reference clock signal input terminal and the frequency difference detection module, for determining which of the spread spectrum clock signal and the reference clock signal has a higher frequency;

a spread spectrum value calculating module connected with the spread spectrum pulse detection module, for calculating a frequency difference between the spread spectrum clock signal and the reference clock signal;

a spread spectrum value reference input terminal, connected with the spread spectrum value calculating module, for inputting a spread spectrum value reference clock; and

an output module, connected with the spread spectrum value calculating module, for outputting an output signal comprising an information of magnitude and direction of a spread spectrum value, wherein the spread spectrum clock signal detection system judges whether the spread spectrum clock signal exists according to the information of the magnitude and direction of the spread spectrum value.

A spread spectrum clock signal detection method, for detecting whether a spread spectrum clock signal exists in a high speed serial data transmission system, comprises steps of:

inputting a spread spectrum clock signal to a frequency difference detection module and a spread spectrum pulse detection module by a spread spectrum clock signal input terminal; inputting a reference clock signal to the frequency difference detection module and the spread spectrum pulse detection module by a reference clock signal input terminal;

detecting whether a frequency difference exists between the spread spectrum clock signal and the reference clock signal by the frequency difference detection module, if the frequency difference exists, proceeding to a next step;

outputting a clock frequency difference denotation impulse to the spread spectrum pulse detection module by the frequency difference detection module; inputting a spread spectrum value reference clock to a spread spectrum value calculating module by a spread spectrum value reference input terminal;

determining which of the spread spectrum clock signal and the reference clock signal has a higher frequency by the spread spectrum pulse detection module, and outputting a spread spectrum value information to the spread spectrum value calculating module by the spread spectrum pulse detection module;

calculating a frequency difference between the spread spectrum clock signal and the reference clock signal by the spread spectrum value calculating module according to the spread spectrum value information and the spread spectrum value reference clock received; and

outputting an output signal comprising an information of magnitude and direction a spread spectrum value with by an output module according to a signal of the frequency difference output by the spread spectrum value calculating module, wherein whether the spread spectrum clock signal exists is judged according to the information of the magnitude and direction of the spread spectrum value.

Compared with prior art, the spread spectrum clock signal detection system and method according to the present invention, could rapidly detect whether the spread spectrum clock signal exists in a high speed serial data transmission system, further verify the correctness of the data sent by the sending terminal accurately and rapidly, and adjust the clock data recovery circuit to work in the best parameters, in such a manner that the EMI radiation could be effectively reduced. The present invention has a simple structure and could be used conveniently.

### BRIEF DESCRIPTION OF THE DRAWINGS

FIG. 1 is a system diagram of a spread spectrum clock signal detection system according to a preferred embodiment of the present invention.

FIG. 2 is an operating principle sketch view of a frequency difference detection module of a spread spectrum clock signal detection system in a half-full state according to a preferred embodiment of the present invention.

FIG. 3 is an operating principle sketch view of a frequency difference detection module of a spread spectrum clock signal detection system in a full state according to the above preferred embodiment of the present invention.

FIG. 4 is an operating principle sketch view of a frequency difference detection module of a spread spectrum clock signal detection system in an empty state according to the above preferred embodiment of the present invention.

FIG. 5 is an operating principle sketch view of a spread spectrum pulse detection module of a spread spectrum clock signal detection system according to a preferred embodiment of the present invention.

FIG. 6 is operating principle sketch view of a spread spectrum value calculating module of a spread spectrum clock signal detection system according to a preferred embodiment of the present invention.

FIG. 7 is a flowchart of a spread spectrum clock signal detection system according to a preferred embodiment of the present invention.

### DETAILED DESCRIPTION OF THE PREFERRED EMBODIMENT

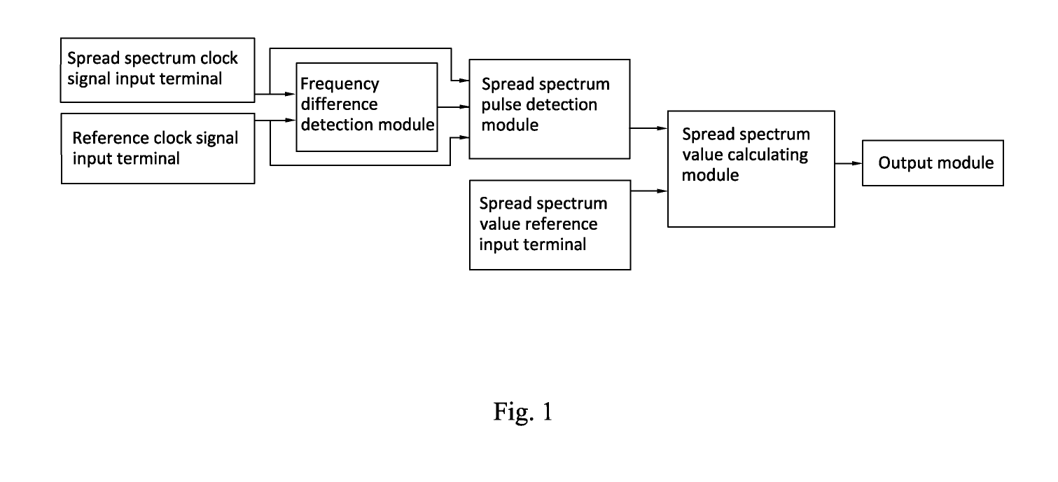

Referring to FIG. 1, a spread spectrum clock signal detection system according to a preferred embodiment of the present invention comprises: a spread spectrum clock signal input terminal; a reference clock signal input terminal; a frequency difference detection module connected with the spread spectrum clock signal input terminal and the reference clock signal input terminal; a spread spectrum pulse detection module connected with the spread spectrum clock signal input terminal, the reference clock signal input terminal and the frequency difference detection module; a spread spectrum value calculating module connected with the spread spectrum pulse detection module; a spread spectrum value reference input terminal connected with the spread spectrum value calculating module; an output module connected with the spread spectrum value calculating module.

The spread spectrum clock signal input terminal is for inputting a spread spectrum clock signal; the reference clock signal input terminal is for inputting a reference clock signal; the frequency difference detection module is for detecting whether a frequency difference exists between the spread spectrum clock signal input by the spread spectrum clock signal input terminal and the reference clock signal input by the reference clock signal input terminal; the spread spectrum pulse detection module determines which has a higher frequency between the spread spectrum clock signal input by the spread spectrum clock signal input terminal and the reference clock signal input by the reference clock signal input terminal according to a pulse signal output by the frequency difference detection module, and outputs a positive spread spectrum value information or a negative spread spectrum value information to the spread spectrum value calculating module; the spread spectrum value reference input terminal is for inputting a spread spectrum value reference clock; the spread spectrum value calculating module calculates the frequency difference between the spread spectrum clock signal input by the spread spectrum clock signal input terminal and the reference clock signal input by the reference clock signal input terminal according to the spread spectrum value information received and the spread spectrum value reference clock; the output module outputs an output signal comprising an information of magnitude and direction of a spread spectrum value according to a signal of the frequency difference, wherein whether the spread spectrum clock signal exists is judged according to the information of the magnitude and direction of the spread spectrum value.

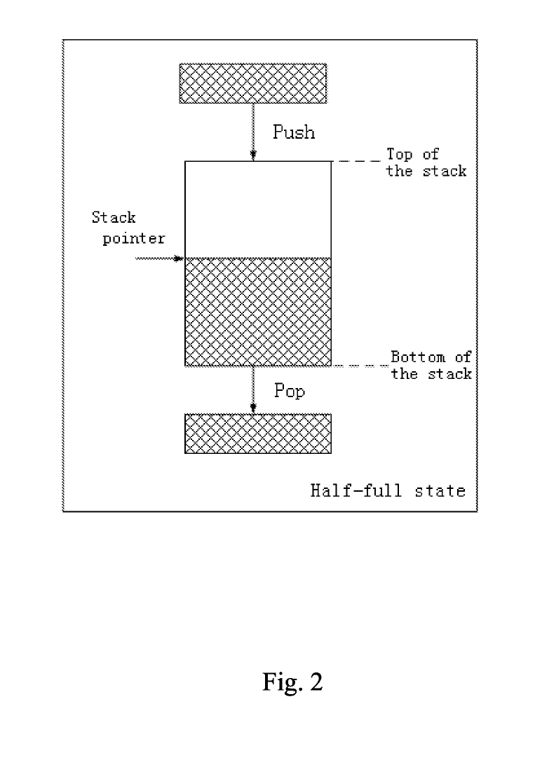

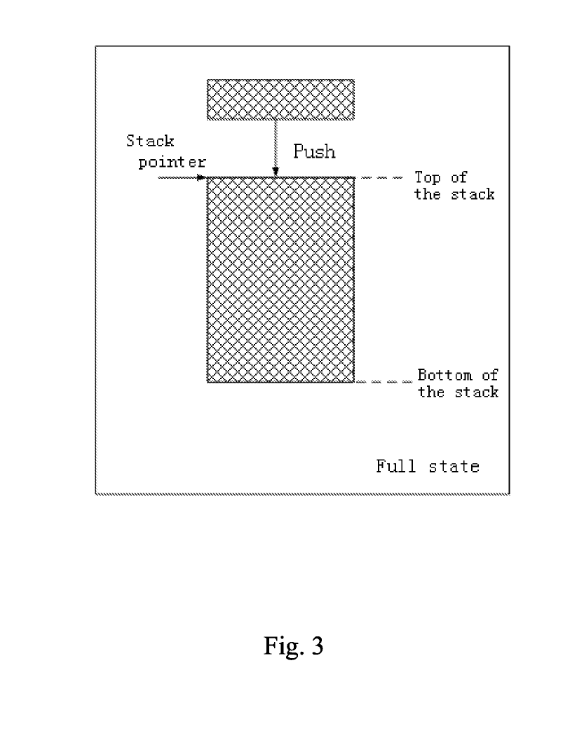

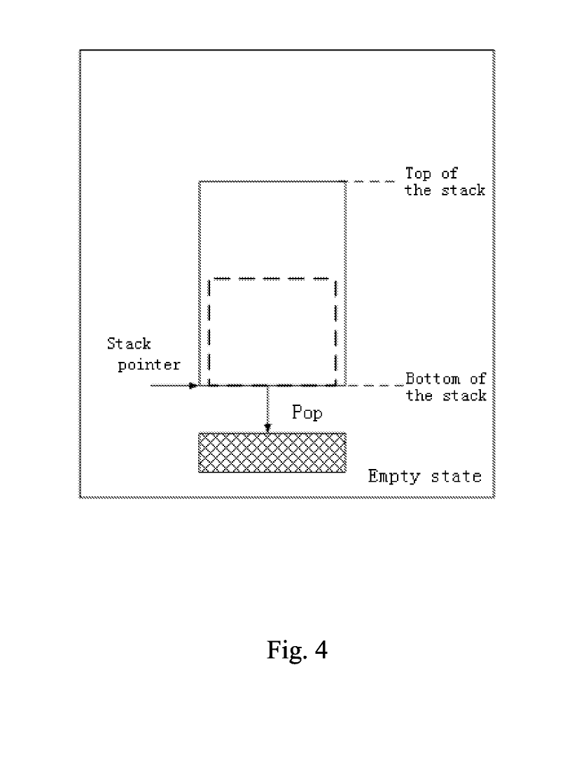

Further referring to FIG. 2, FIG. 3 and FIG. 4, FIG. 2, FIG. 3 and FIG. 4 are operating principle state sketch views of a frequency difference detection module of a spread spectrum clock signal detection system according to a preferred embodiment of the present invention. The frequency difference detection module comprises a limited depth first-in first-out register, and the spread spectrum clock signal input by the spread spectrum clock signal input terminal and the reference clock signal input by the reference clock signal input terminal respectively control a push operation and a pop operation of the limited depth first-in first-out register asynchronously. When the frequency difference detection module is powered on to work, the limited depth first-in first-out register enters into a half-full state first as shown in FIG. 2. According to whether the frequency difference exists between the spread spectrum clock signal input by the spread spectrum clock signal input terminal and the reference clock signal input by the reference clock signal input terminal, there are a plurality of responses as follows.

(1) When the frequency difference between the spread spectrum clock signal input by the spread spectrum clock signal input terminal and the reference clock signal input by the reference clock signal input terminal doesn't exist, as referring to FIG. 2, in the limited depth first-in first-out register, a number of the push operation in unit time is equal to a number of the pop operation in unit time, the limited depth first-in first-out register keeps in the half-full state.

(2) When a frequency of the spread spectrum clock signal input by the spread spectrum clock signal input terminal is higher than a frequency of the reference clock signal input by the reference clock signal input terminal, as referring to FIG. 3, in the limited depth first-in first-out register, the number of the push operation in unit time is more than the number of the pop operation in unit time, a stack of the limited depth first-in first-out register will be filled up, and a stack pointer of the stack is located in a top of the stack; When a new push instruction is given, the frequency difference detection module will output a clock frequency difference denotation impulse, and the limited depth first-in first-out register will be reset to the half-full state, as referring to FIG. 2.

(3) When a frequency of the spread spectrum clock signal input by the spread spectrum clock signal input terminal is lower than a frequency of the reference clock signal input by the reference clock signal input terminal, as referring to FIG. 4, in the limited depth first-in first-out register, the number of the push operation in unit time is less than the number of the pop operation in unit time, the stack of the limited depth first-in first-out register will be emptied, and a stack pointer of the stack is located in a bottom of the stack; When a new pop instruction is given, the frequency difference detection module will also output the clock frequency difference denotation impulse, and the limited depth first-in first-out register will be reset to the half-full state, as referring to FIG. 2.

The frequency difference detection module detects whether the frequency difference exists between the spread spectrum clock signal input by the spread spectrum clock signal input terminal and the reference clock signal input by the reference clock signal input terminal according to the above operating principle. When the frequency difference exists, the frequency difference detection module outputs the clock frequency difference denotation impulse to the spread spectrum pulse detection module, the spread spectrum pulse detection module determines which has a higher frequency between the spread spectrum clock signal input by the spread spectrum clock signal input terminal and the reference clock signal input by the reference clock signal input terminal, and outputs the positive spread spectrum value information or the negative spread spectrum value information to the spread spectrum value calculating module, the spread spectrum value calculating module calculates the frequency difference between the spread spectrum clock signal input by the spread spectrum clock signal input terminal and the reference clock signal input by the reference clock signal input terminal according to the spread spectrum value information received and the spread spectrum value reference clock input by the spread spectrum value reference input terminal, the output module outputs the output signal comprising the information of the spread spectrum value with magnitude and direction according to the signal of the frequency difference, wherein whether the spread spectrum clock signal exists is judged according to the information of the spread spectrum value with magnitude and direction; when the frequency difference doesn't exist, the frequency difference detection module outputs a free instruction signal to spread spectrum pulse detection module, and the spread spectrum pulse detection module keeps in a current state.

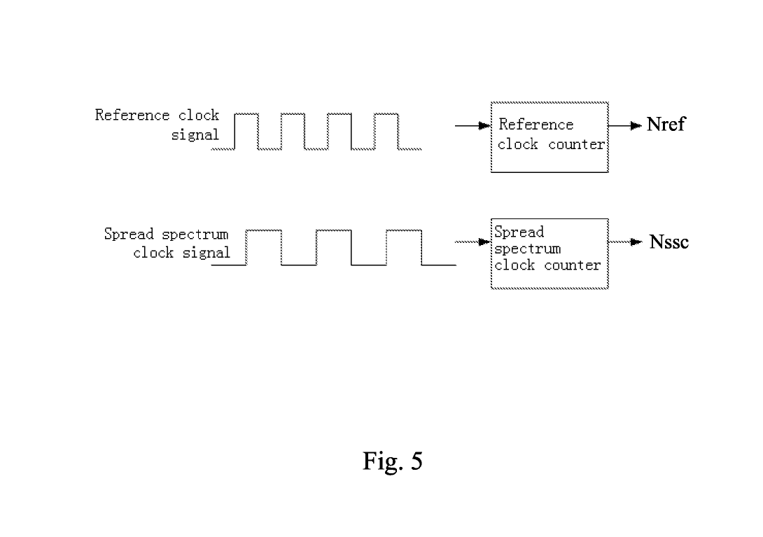

Referring to FIG. 5, FIG. 5 is an operating principle sketch view of a spread spectrum pulse detection module of a spread spectrum clock signal detection system according to a preferred embodiment of the present invention. The spread spectrum pulse detection module comprises a reference clock counter and a spread spectrum clock counter, the reference clock counter counts the reference clock signals input by the reference clock signal input terminal and outputs a counting result Nref, the spread spectrum clock counter counts the spread spectrum clock signal input by the spread spectrum clock signal input terminal and outputs a counting result Nssc. When Nssc<Nref, the spread spectrum pulse detection module outputs the negative spread spectrum value information, when Nssc>Nref, the spread spectrum pulse detection module outputs the positive spread spectrum value information.

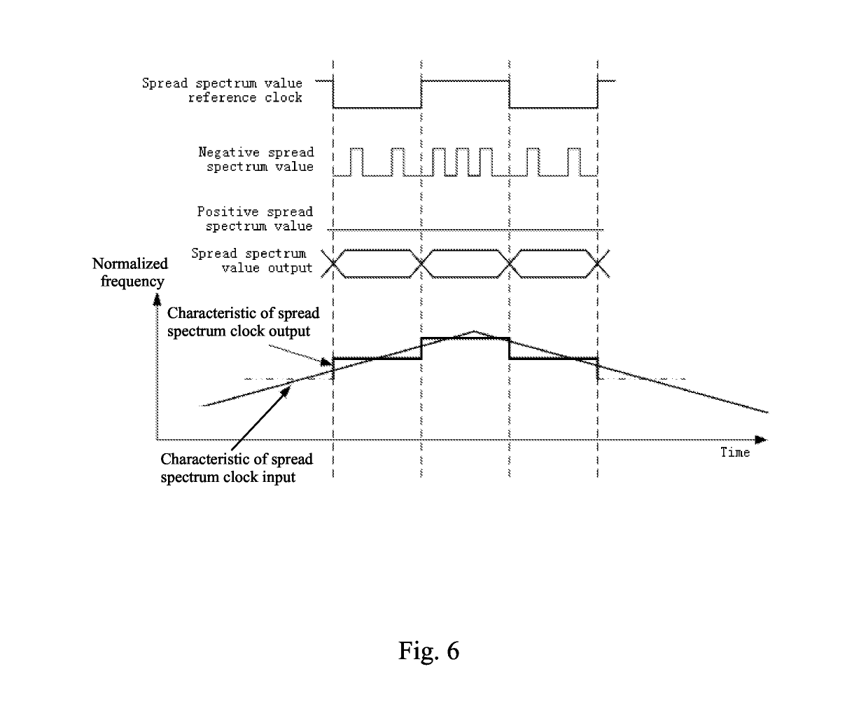

Referring to FIG. 6, FIG. 6 is operating principle sketch view of a spread spectrum value calculating module of a spread spectrum clock signal detection system according to a preferred embodiment of the present invention. If the spread spectrum pulse detection module outputs the negative spread spectrum value information to the spread spectrum value calculating module, the spread spectrum reference input terminal will input a low-speed spread spectrum value reference clock for quantifying a spread spectrum period. The spread spectrum value reference clock counts the negative spread spectrum value information output by the spread spectrum pulse detection module, and writes a counting result of a round into a register at a moment that a level switches. The spread spectrum value calculating module calculates the frequency difference between the spread spectrum clock signal input by the spread spectrum clock signal input terminal and the reference clock signal input by the reference clock signal input terminal by reading a spread spectrum period and a spread spectrum value of the spread spectrum clock in the register, to generate a spread spectrum output signal, and obtains an characteristic of the spread spectrum clock output as shown in FIG. 6. The output module compares the characteristic of the spread spectrum clock output with a characteristic of the spread spectrum clock input, and outputs an output signal comprising an information of magnitude and direction of a spread spectrum value according to the signal of the frequency difference received, wherein whether the spread spectrum clock signal exists is judged according to the information of the magnitude and direction of the spread spectrum value of the output signal.

The operating principle of a spread spectrum clock signal detection system according to a preferred embodiment of the present invention is as follows.

The spread spectrum clock signal input terminal inputs a spread spectrum clock signal to the frequency difference detection module and the spread spectrum pulse detection module, the reference clock signal input terminal inputs a reference clock signal to the frequency difference detection module and the spread spectrum pulse detection module, the spread spectrum value reference input terminal inputs a spread spectrum value reference clock to the spread spectrum value calculating module; the frequency difference detection module detects whether the frequency difference exists between the spread spectrum clock signal input by the spread spectrum clock signal input terminal and the reference clock signal input by the reference clock signal input terminal, if the frequency difference exists, the frequency difference detection module will output a clock frequency difference denotation impulse to the spread spectrum pulse detection module, if the frequency difference doesn't exist, the frequency difference detection module will output a free instruction signal to the spread spectrum pulse detection module; when the spread spectrum pulse detection module receives the clock frequency difference denotation impulse output by the frequency difference detection module, the spread spectrum pulse detection module determines which has a higher frequency between the spread spectrum clock signal input by the spread spectrum clock signal input terminal and the reference clock signal input by the reference clock signal input terminal and outputs a positive spread spectrum value information or a negative spread spectrum value information to the spread spectrum value calculating module; when the spread spectrum pulse detection module receives the free instruction signal output by the frequency difference detection module, the spread spectrum pulse detection module keeps in the current state; the spread spectrum value calculating module calculates the frequency difference between the spread spectrum clock signal input by the spread spectrum clock signal input terminal and the reference clock signal input by the reference clock signal input terminal according to the spread spectrum value information received and the spread spectrum value reference clock input by the spread spectrum value reference input terminal; the output module outputs an output signal comprising an information of magnitude and direction of a spread spectrum value according to the signal of the frequency difference received, wherein whether the spread spectrum clock signal exists is judged according to the information of the magnitude and direction of the spread spectrum value of the output signal.

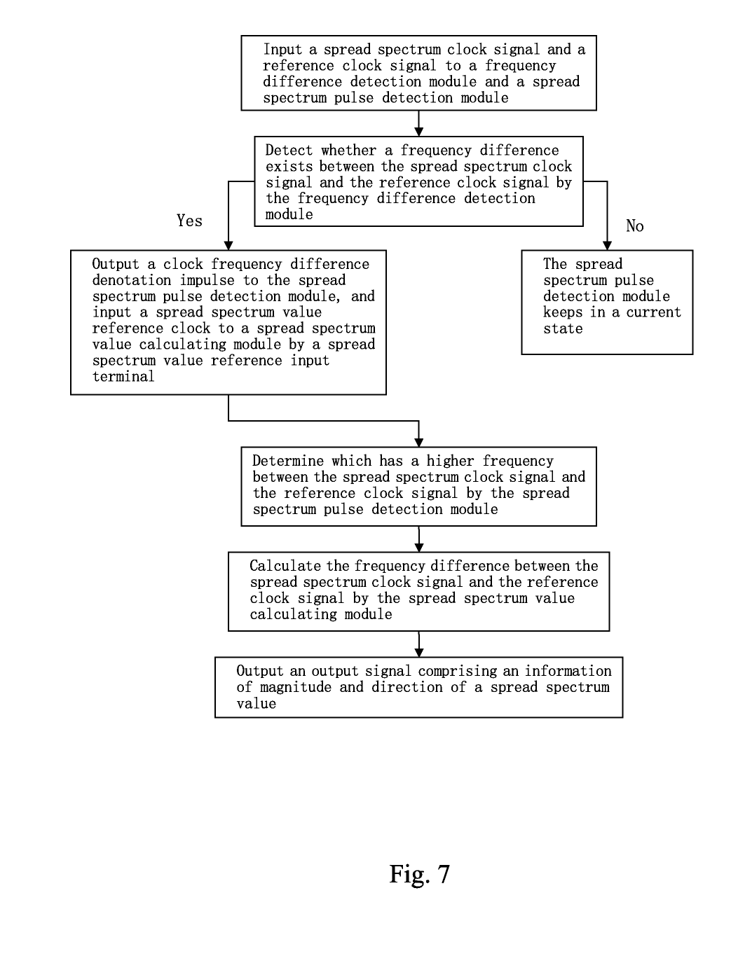

Referring to FIG. 7, a spread spectrum clock signal detection method, according to a preferred embodiment of the present invention, comprises steps of:

inputting a spread spectrum clock signal to a frequency difference detection module and a spread spectrum pulse detection module by a spread spectrum clock signal input terminal; inputting a reference clock signal to the frequency difference detection module and the spread spectrum pulse detection module by a reference clock signal input terminal;

determining whether a frequency difference exists between the spread spectrum clock signal input by the spread spectrum clock signal input terminal and the reference clock signal input by the reference clock signal input terminal by the frequency difference detection module, if the frequency difference exists, proceeding to a next step, if the frequency difference doesn't exist, the frequency difference detection module will output a free instruction signal to the spread spectrum pulse detection module, and the spread spectrum pulse detection module will keep in the current state;

outputting a clock frequency difference denotation impulse to the spread spectrum pulse detection module by the frequency difference detection module; inputting a spread spectrum value reference clock to a spread spectrum value calculating module by a spread spectrum value reference input terminal;

determining which has a higher frequency between the spread spectrum clock signal input by the spread spectrum clock signal input terminal and the reference clock signal input by the reference clock signal input terminal, and outputting a positive spread spectrum value information or a negative spread spectrum value information to the spread spectrum value calculating module by the spread spectrum pulse detection module;

calculating the frequency difference between the spread spectrum clock signal input by the spread spectrum clock signal input terminal and the reference clock signal input by the reference clock signal input terminal by the spread spectrum value calculating module, according to the spread spectrum value information received and the spread spectrum value reference clock input by the spread spectrum value reference input terminal; and

outputting an output signal comprising an information of magnitude and direction of a spread spectrum value according to a signal of the frequency difference received, wherein whether the spread spectrum clock signal exists is judged according to the information of the magnitude and direction of the spread spectrum value of the output signal.

The spread spectrum clock signal detection system and method according to the present invention, could rapidly detect whether the spread spectrum clock signal exists in a high speed serial data transmission system, further verify the correctness of the data sent by the sending terminal accurately and rapidly, and adjust the clock data recovery circuit to work in the best parameters, in such a manner that the EMI radiation could be reduced effectively. The present invention has a simple structure and could be used conveniently.

What is claimed is:

1. A spread spectrum clock signal detection system for detecting whether a spread spectrum clock signal exists in a high speed serial data transmission system comprising:
a spread spectrum clock signal input terminal for inputting said spread spectrum clock signal;
a reference clock signal input terminal for inputting a reference clock signal;
a frequency difference detection module, connected with said spread spectrum clock signal input terminal and said reference clock signal input terminal, for detecting whether a frequency difference exists between said spread spectrum clock signal and said reference clock signal;
a spread spectrum pulse detection module, connected with said spread spectrum clock signal input terminal, said reference clock signal input terminal and said frequency difference detection module, for determining which has a higher frequency between said spread spectrum clock signal and said reference clock signal;
a spread spectrum value calculating module, connected with said spread spectrum pulse detection module, for calculating said frequency difference between said spread spectrum clock signal and said reference clock signal;
a spread spectrum value reference input terminal, connected with said spread spectrum value calculating module, for inputting a spread spectrum value reference clock; and
an output module, connected with said spread spectrum value calculating module, for outputting an output signal comprising an information of magnitude and direction of a spread spectrum value, wherein said spread spectrum clock signal detection system judges whether said spread spectrum clock signal exists according to said information of said magnitude and direction of said spread spectrum value.

2. The spread spectrum clock signal detection system, as recited in claim 1, wherein said spread spectrum pulse detection module determines which has a higher frequency between said spread spectrum clock signal and said reference clock signal, and outputs a spread spectrum value information to said spread spectrum value calculating module, said spread spectrum value information is positive or negative.

3. The spread spectrum clock signal detection system, as recited in claim 1, wherein said spread spectrum pulse detection module comprises: a reference clock counter for counting said reference clock signal, and a spread spectrum clock counter for counting said spread spectrum clock signal, said spread spectrum pulse detection module compares a counting result of said reference clock counter with a counting result of said spread spectrum clock counter, and outputs a spread spectrum value information to said spread spectrum value calculating module.

4. The spread spectrum clock signal detection system, as recited in claim 1, wherein said frequency difference detection module comprises a limited depth first-in first-out register, said spread spectrum clock signal input by said spread spectrum clock signal input terminal and said reference clock signal input by said reference clock signal input terminal respectively control a push operation and a pop operation of said limited depth first-in first-out register asynchronously.

5. The spread spectrum clock signal detection system, as recited in claim 4, wherein when said frequency difference detection module detects that said frequency difference exists between said spread spectrum clock signal and said reference clock signal, said frequency difference detection module outputs a clock frequency difference denotation impulse to said spread spectrum pulse detection module.

6. The spread spectrum clock signal detection system, as recited in claim 4, wherein when said frequency difference detection module detects that said frequency difference doesn't exist between said spread spectrum clock signal and said reference clock signal, said frequency difference detection module outputs a free instruction signal to said spread spectrum pulse detection module, and said spread spectrum pulse detection module will keep in a current state.

7. A spread spectrum clock signal detection method, for detecting whether a spread spectrum clock signal exists in a high speed serial data transmission system, comprises steps of:
inputting a spread spectrum clock signal to a frequency difference detection module and a spread spectrum pulse detection module by a spread spectrum clock signal input terminal; inputting a reference clock signal to the frequency difference detection module and the spread spectrum pulse detection module by a reference clock signal input terminal;
determining whether a frequency difference exists between the spread spectrum clock signal and the reference clock signal, if the frequency difference exists, proceeding to a next step;
outputting a clock frequency difference denotation impulse to the spread spectrum pulse detection module by the frequency difference detection module, and inputting a spread spectrum value reference clock to a spread spectrum value calculating module by a spread spectrum value reference input terminal;
determining which has a higher frequency between the spread spectrum clock signal and the reference clock signal, and outputting a spread spectrum value information to the spread spectrum value calculating module;
calculating the frequency difference between the spread spectrum clock signal and the reference clock signal by the spread spectrum value calculating module according to the spread spectrum value information received and the spread spectrum value reference clock; and
outputting an output signal comprising an information of magnitude and direction of a spread spectrum value according to a signal of the frequency difference output by the spread spectrum value calculating module, wherein whether the spread spectrum clock signal exists is judged according to the information of the magnitude and direction of the spread spectrum value.

8. The spread spectrum clock signal detection method, as recited in claim 7, wherein when the frequency difference detection module detects that the frequency difference doesn't exist between said spread spectrum clock signal and said reference clock signal, the frequency difference detection module outputs a free instruction signal to the spread spectrum pulse detection module.

9. The spread spectrum clock signal detection method, as recited in claim 7, wherein the spread spectrum pulse detection module comprises: a reference clock counter for counting the reference clock signal, and a spread spectrum clock counter for counting the spread spectrum clock signal, the spread spectrum pulse detection module compares a counting result of the reference clock counter with a counting result of the spread spectrum clock counter, and outputs the spread spectrum value information to the spread spectrum value calculating module, the spread spectrum value information is positive or negative.

10. The spread spectrum clock signal detection method, as recited in claim 7, wherein the frequency difference detection module comprises a limited depth first-in first-out register, the spread spectrum clock signal input by the spread spectrum clock signal input terminal and the reference clock signal input by the reference clock signal input terminal respectively control a push operation and a pop operation of the limited depth first-in first-out register asynchronously.
